(19) United States
(12) Patent Application Publication
(10) Pub. No.: US 2006/0157829 A1
(43) Pub. Date: Jul. 20, 2006

(54) Lead frame, semiconductor device comprising the lead frame and method of manufacturing a semiconductor device with the leadframe

(75) Inventors: Paulus Martinus Catharina Hesen, Nijmegen (NL); Peter Wilhelmus Maria Van De Water, Nijmegen (NL); Cornelis Gerardus Schriks, Nijmegen (NL)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(73) Assignee: KONINKLIJKE PHILLIPS ELECTRONICS N.C.

(21) Appl. No.: 10/560,447

(22) PCT Filed: Jun. 14, 2004
(86) PCT No.: PCT/IB04/50896

§ 371 Date: Dec. 12, 2005

(30) Foreign Application Priority Data
Jun. 18, 2003 (EP) 03101790.8

(51) Int. Cl. H01L 23/495

(52) U.S. Cl. 257/666

(57) ABSTRACT

A semiconductor element (3) is mounted on a flat lead frame (11, 11 A) which is provided with two connection conductors (4, 5) in between which the element (3) is attached, and the element (3) is positioned on the first conductor (4) and the second conductor is brought to a position above that of the element (3) by a movement outside the plane of the lead frame (11, 11 A). The end part of the second conductor (5) is positioned within the frame (11 A) outside the longitudinal position of the first conductor (4) and is brought to a position above the position of the element (3) by means of bending along a bending axis. The bending axis makes an oblique angle with the longitudinal axis of the end part. In this manner, a semiconductor device is obtained comprising as a semiconductor element at least one diode or transistor.

The invention relates to a lead frame provided with a frame having a first and a second connection conductor, where, after deformation, the end portion of the second connection conductor can be positioned opposite the first connection conductor, and a semiconductor element can be placed between said connection conductors.

The invention also relates to methods of manufacturing a semiconductor device comprising the steps of providing a semiconductor element provided with a first and a second electric connection region, which connection regions are situated on opposite sides of the semiconductor element; providing a lead frame comprising a frame with a first and a second connection conductor, which connection conductors are each connected to the frame and provided with an exposed end portion; attaching the semiconductor element to the end portion of the first connection conductor, an electroconductive connection between the first connection region and the end portion by using a connection means; and making an electroconductive connection between the second connection region and the end portion of the second connection conductor using a connection means. Such a method enables, in particular discrete semiconductor devices with, for example, a diode or a transistor as the semiconductor element, to be readily manufactured.

A lead frame and a method of the type mentioned in the opening paragraph are known from Japanese patent specification JP-04-338640, published under number JP-A-06-188346 on Jul. 8, 1994. Said document describes that, in a plane frame of a lead frame, two strip-shaped connection conductors are defined on two opposite sides of the lead frame. One connection conductor is provided, near the exposed end portion thereof, of a semiconductor element, the other connection conductor is attached at one end or in the center, to the lead frame by means of two narrow (metal) strips situated on either side of the connection conductor. By rotating this connection conductor through 180 degrees, where the axis of rotation extends along said narrow strips, the connection conductor is moved out of the plane of the frame and rotated to a position above the position of the semiconductor element. Next, this conductor is attached to the (upper side of) the semiconductor element.

A drawback of the known lead frame and of the known method is that said lead frame is less suitable for the manufacture of devices comprising, in particular, semiconductor elements such as transistors. In that case, two strip-shaped connection conductors must be attached to one side of the element because a transistor requires three connection conductors. This cannot be easily achieved with the method described above, in particular if the semiconductor element has comparatively small dimensions. If so, it is no longer readily possible to manufacture the two connection conductors to be rotated as well as their connection to the lead frame by means of the narrow strips such that they are sufficiently large and strong.

The first object of the present invention therefore is to provide a lead frame of the type mentioned in the opening paragraph, wherein said drawback is obviated or at least substantially reduced, and which lead frame is particularly suitable for the manufacture of semiconductor devices which require more than two connection conductors and, in addition, have comparatively small dimensions.

It is a second object of the invention to provide methods of the type mentioned in the opening paragraph, which enable semiconductor devices having small dimensions to be manufactured.

To achieve this, in accordance with the invention, a lead frame of the type mentioned in the opening paragraph is characterized in that the end portion of the second connection conductor within the frame is positioned outside the extension of the first connection conductor and can be brought to a position opposite the position of the semiconductor element by bending along a bending axis which is at an oblique angle with respect to the longitudinal axis of the end portion.

To achieve this, in accordance with the invention, a first method of the type mentioned in the opening paragraph is characterized in that the lead frame in accordance with the invention is applied after the end portion for the second connection conductor has been brought to a position opposite the position of the second connection region by bending.

To achieve this, in accordance with the invention, a second method of the type mentioned in the opening paragraph is characterized in that the end portion of the second connection conductor within the frame is positioned outside the extension of the first connection conductor, and is brought to a position opposite the position for the second connection region of the semiconductor element by bending along a bending axis that is at an oblique angle with respect to the longitudinal axis of the end portion.

The invention is based first of all on the recognition that larger and stronger connection conductors are possible if the use of narrow strips for fastening and rotation of the connection conductors past these strips can be dispensed with. The invention is further based on the fact that part of the connection conductors to be displaced can readily be held in the plane of the frame, for example, by placing a packing block on said frame. At the same time, part of the connection conductors may be bent instead of rotated in order to be brought from the plane of the frame to a position above the position of the semiconductor element. By carrying out said bending operation along a bending axis that makes an oblique angle with the longitudinal axis of the (parts of the) strip-shaped connection conductors, these connection conductors can be readily brought to above the desired position(s) above the position of the semiconductor element, irrespective of the (lateral) dimensions of the connection conductors and irrespective of the position with respect to one another and with respect to the connection conductor containing the position for the element. This may be readily achieved by choosing the geometry and orientation of the part of the connection conductor to be bent in such a manner that, in a mirror-reflected position with respect to the bending axis, it is in the desired position. This mirror-reflected position, as a matter of fact, is the position that is achieved after bending through 180 degrees. Although this method is particularly suitable for semiconductor elements with three or more terminals, such as transistors, the invention may also be applied to semiconductor elements having two connection conductors.

The methods of manufacturing a semiconductor device may be used as mutual alternatives. In the fist method, bending takes place already during the manufacture of the lead frame, and the lead frame thus obtained is applied for the assembly process. In the second method, bending is effected no sooner than during the assembly of the element and the lead frame, and possibly after the element has been placed on the first connection conductor.

Embodiments for bending the lead frame:

In a preferred embodiment of the second method in accordance with the invention, the end portion of the second connection conductor is bent through approximately 90 degrees out of the plane of the frame, and the end of the end portion is bent, along a further bending axis extending substantially parallel to the bending axis and at a distance therefrom corresponding approximately to the thickness of the semiconductor element, through an angle of approximately 90 degrees to the position of the semiconductor element. The part of the end portion situated between the axes is of course maintained in the position of 90 degrees with respect to the frame. In the first place, it is easier to carry out the bending process in two steps because the associated deformation and introduction of stress are smaller. Secondly, it thus becomes easier to make the two connection conductors extend, at the location of the position of the semiconductor element, in directions that are substantially parallel or that include an angle with each other which can be chosen more or less freely. Also calibrating, where necessary, thus becomes easier.

Preferably, the end portion of the second connection conductor is bent along the further bending axis or along another bending axis in such a manner that said end portion extends obliquely in at least one direction with respect to the end portion of the first connection conductor which contains the position for the semiconductor element. The semiconductor element can thus be readily clamped between the conductors, if the semiconductor element is not brought to the intended position on the first conductor until after the second connection conductor has been bent. Particularly in the case of a transistor, it is advantageous if the second and a further connection conductor, which will both be bent, extend obliquely in two directions with respect to the first connection conductor, after they have been bent.

Besides a clamping effect, this also has a directing (self-aligning) effect on the element if said element is slid between the connection conductors. By virtue thereof, industrial application, i.e. mass-production, is facilitated.

Embodiments for placing the semiconductor element:

As indicated, the semiconductor element may be provided on the lead frame either before or after the bending operation.

In a particularly favorable modification, the semiconductor element is slid between the connection conductors after one connection conductor has been brought to a position above the other connection conductor by bending. Preferably, in view thereof, the first connection conductor is provided with a hole at some distance anterior to the position of the semiconductor element, on which hole the semiconductor element is placed and subsequently fixed by means of a suction device present below the hole, after which the semiconductor element is slid between the connection conductors by means of a pusher member, after bending one connection conductor to a position above the other connection conductor.

In another modification, where the semiconductor element is slid between the two connection conductors from the other side, the end portion of the first connection conductor is maintained in a depressed position by means of a pressure member until the semiconductor element has been slid between the connection conductors. In this manner, the semiconductor element can be positioned on the substrate on which also the lead frame rests. This substrate is then provided with a recess at the location of the first connection conductor. By pressing this connection conductor downward over a distance which corresponds to the thickness of said connection conductor, the element can be moved in a flat plane to the intended position on the first connection conductor.

After the element has been slid between the conductors, it is electroconductively connected thereto. For this purpose use may be made of for example solder balls or solder that are situated on the element or on a side of the conductors facing the element. Next, the element is preferably provided with a passivating synthetic resin envelope, after which the redundant parts are removed from the lead frame.

The invention further relates to a device which is suitable for carrying out a method in accordance with the invention. This is characterized in that the device is provided with a transport mechanism for a lead frame with at least two connection conductors, and with positioning means for positioning a semiconductor element, and with pusher means for pushing the semiconductor element is between the two conductors, of which one has been bent to a position above the position of the other.

A device which is suitable for all steps of the second method additionally comprises means for bending at least one of the connection conductors along a bending axis which makes an oblique angle with the longitudinal axis.

In a favorable modification, where the element is not slid over a conductor to its position, the device also comprises pressure means for pressing downward one of the conductors when a pushing force is being exerted on the semiconductor element.

The invention finally relates to a semiconductor device comprising a semiconductor element provided with a first and a second electric connection region, which connection regions are situated on opposite sides of the semiconductor element; a first connection conductor with a contact and, facing away therefrom, an end portion which is electroconductive connected to the first connection region; a second connection conductor with a contact and, facing away therefrom, an end portion which is situated opposite the second electric connection region, with which it is electroconductively connected, while the contact is situated in the same plane as the contact of the first connection conductor; and an isolating envelope leaving contact facing away from the end portions of the connection conductors uncovered.

Such a semiconductor device is known from the above-mentioned Japanese document. This device has the drawback that the envelope has large dimensions as compared to the semiconductor element. This can be attributed to the connection conductors, which are strip-shaped.

Therefore, it is an object of the invention to provide a semiconductor device of the type mentioned in the opening paragraph, which has smaller dimensions.

This object is achieved in that the end portion of the second connection conductor is bent along a bending axis which is at an oblique angle with respect to the longitudinal axis of the end portion. By bending through an oblique angle, the one or more folds do not extend along the longitudinal axis of the connection conductor, but substantially along a side face of the semiconductor element. This results in a substantial saving of space since, in order to prevent fracture, an angle will never be exactly 90 degrees. Besides, space is saved because the known device is obtained by rotation of the connection conductor through an axis perpendicular to the connection conductor. This axis cannot be defined close to the semiconductor element, the distance between axis and semiconductor element is determined by the desired length of the contact at the connection conductor. After the rotation, the part originally situated between axis and semiconductor element has shifted to the outside and serves as a contact.

In a first embodiment, the semiconductor element is a semiconductor diode. The second connection conductor is u-shaped or j-shaped prior to bending, and the oblique angle is chosen to range between 70 and 80 degrees. As a result, the contacts of the connection conductors are in line with each other.

In a second embodiment, the semiconductor element is a semiconductor transistor with a third connection region. For this reason, there is also a third connection conductor having a contact and an end portion facing away from said contact. This end portion is bent along a bending axis which extends at an oblique angle with respect to the longitudinal axis of the end portion, such that the end portion is situated opposite the third electric connection region, with which it is electroconductively connected, while the contact is situated in the same plane as the contact of the first connection conductor. This embodiment is not known from said prior-art document and cannot be realized at all, or only with difficulty, if use is made of the lead frame described therein.

Advantageously, the second and third connection conductor are situated on either side of the first connection conductor, and the oblique angles are angles of approximately 45 degrees. In this manner, the space obtained is optimally used, and the semiconductor device can be maximally miniaturized.

It is additionally possible that the semiconductor device accommodates more than one semiconductor element, in which case one of the connection conductors can be used as an interconnect. The first connection conductor is preferably used for this purpose.

It is also advantageous if the first connection conductor is provided with a hole at a distance from the position for the semiconductor element. Such a hole simplifies the manufacture of the device.

These and other aspects of the invention are apparent from and will be elucidated with reference to the embodiment(s) described hereinafter.

In the drawings:

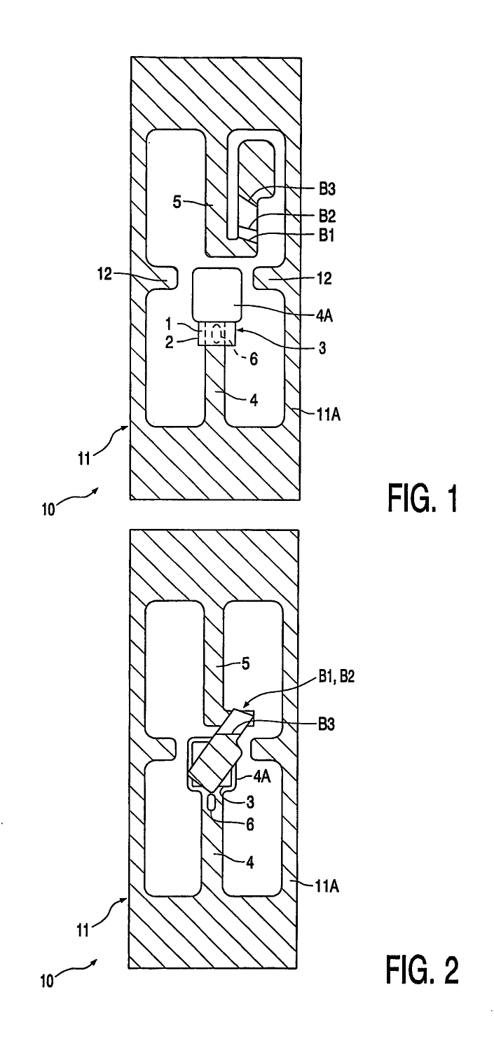

FIGS. 1 and 2 are diagrammatic plan views of an embodiment of a semiconductor device with a diode in successive stages of the manufacture carried out by means of a method in accordance with the invention,

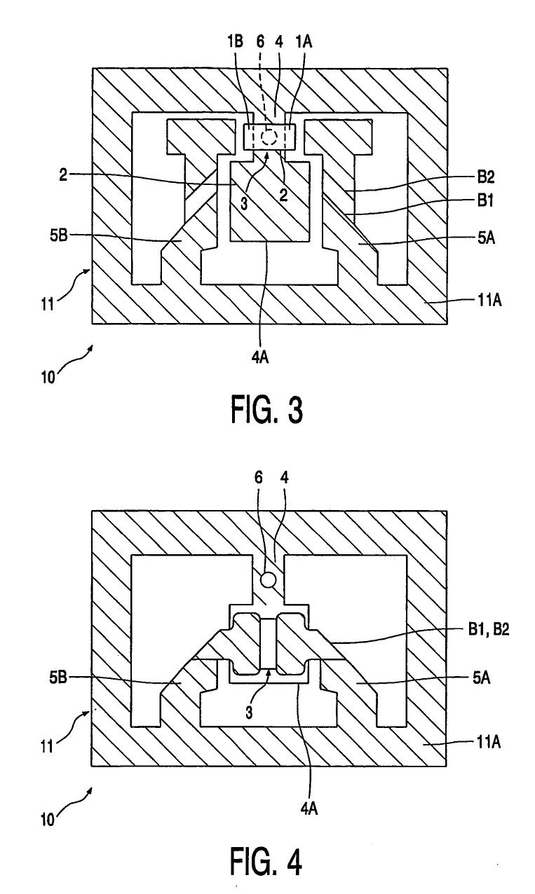

FIGS. 3 and 4 are diagrammatic plan views of an embodiment of a semiconductor device with a transistor in successive stages of the manufacture carried out by means of a method in accordance with the invention,

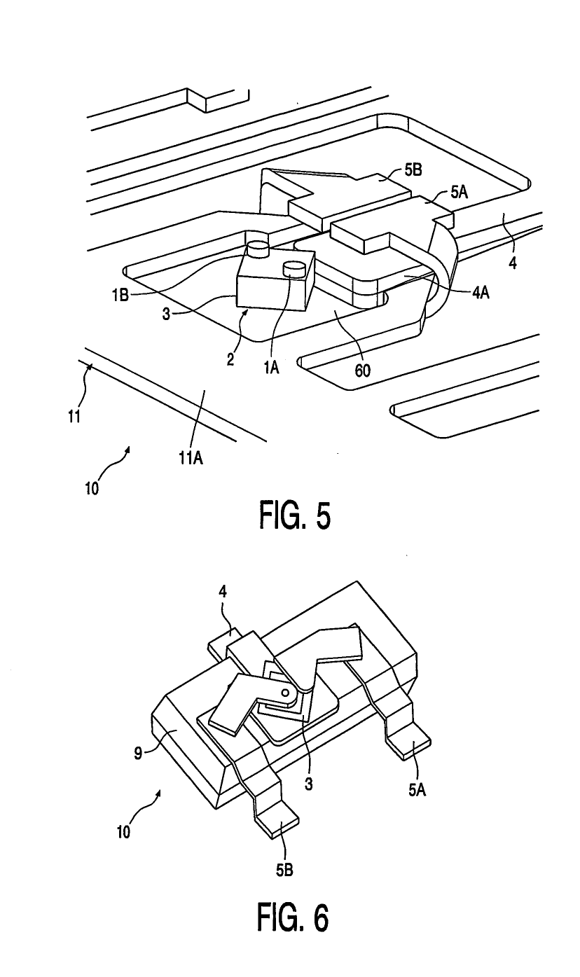

FIG. 5 is a diagrammatic perspective view of an embodiment of a semiconductor device with a transistor in a stage of the manufacture carried out by means of a modification of a method in accordance with the invention,

FIG. 6 diagrammatically shows a perspective, phantom view of a semiconductor device with a transistor in an end stage of the manufacture with the aid of a method in accordance with the invention, and

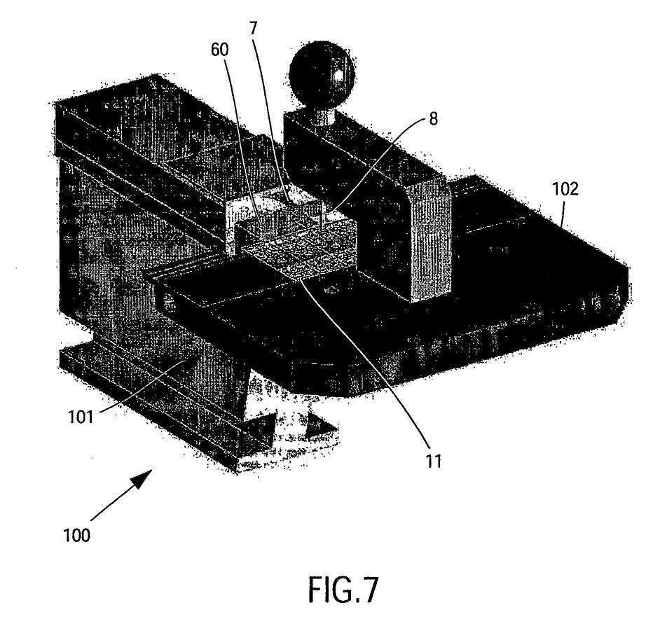

FIGS. 7 through 9 are diagrammatic, perspective views of a device for carrying out a method in accordance with the invention.

The Figures are not drawn to scale and some dimensions, such as dimensions in the thickness direction, are exaggerated for clarity. In the various Figures, like areas or parts are indicated by means of the same reference numerals, whenever possible.

FIGS. 1 and 2 are diagrammatic, plan views of an embodiment of a semiconductor device with a diode in successive stages of the manufacture carried out by means of a method in accordance with the invention. A flat lead frame 11 (see FIG. 1) is used as the starting structure and comprises a frame 11 to which two strip-shaped connection conductors 4, 5 are attached. The first conductor 4 has an enlarged end portion 4A which forms a suitable position for a semiconductor element 3, in this case a diode 3. Directly before the position 4A for the element 3, there is a hole 6 in the conductor 4. Via said hole 6 a diode 3, which is placed above the hole 6 on the conductor 4, for example by means of (vacuum) tweezers, can be maintained in position by means of a suction device, not shown, which is situated below the hole 6. On an opposite side of the frame 11A, a second strip-shaped connection conductor 5 is attached to said frame, a first part of said second strip-shaped connection conductor being in line with the conductor 4, and a second part, forming an end portion of the conductor 5, being formed so as to be situated along the first part and face the side of attachment thereof. The second part is widened near its end portion and is further provided with a folding line B1 and, in this case, also of two further folding lines B2, B3 which may serve as bending axes of the second part of the conductor 5. The entire second part can be rotated along the bending axis B through 180 degrees out of the plane of the frame.

In this example, however, (see FIG. 2) the second part of the second connection conductor 5 is bent upwards along the axis (and folding line) B1 through 90 degrees. Next, this part is bent again through approximately 90 degrees, in this case slightly more than 90 degrees, along the second axis (and folding line) B2, as a result of which the end portion of the second conductor is bent to a position above the position 4A of the first conductor 4. The fact that this is possible is determined, apart from the geometry and position of the second part of the second conductor 5, by the position and orientation of the bending axis B1. These are such that after the part of the second conductor 5 which is situated above the axis B1 in FIG. 1, has been mirror-reflected with respect to the axis B1, said part becomes situated exactly in the desired position above the end portion 4A of the first conductor 4. To achieve this, it is necessary that the axis B1 makes an oblique angle with the longitudinal axis of the conductor 5. In this example, said angle is approximately 75 degrees. The distance between the axes B1, B2 is chosen to be approximately equal to the thickness of the element 3 to be placed. In this example (after it has been bent twice through, respectively, 90 and 75 degrees) the end portion of the second conductor 5 is additionally bent through a small angle of, in this case, approximately 10 degrees along the bending axis B3. Said bending axis makes an oblique angle of approximately 60 degrees with the longitudinal axis of the conductor 5. In the final state, the part of the conductor 5 that is situated above the position 4A of the first conductor 4 then makes a small angle with the conductor 4. An advantage of this modification, where the conductors 4, 5 are attached on opposite sides of the frame 11A, is that the frame 11A may be provided with, occasionally desired, bulges 12 on two sides of the position 4A for the element 3.

Next, the diode 3 is slid from the position shown in FIG. 1 to the position shown in FIG. 2 and fixed between the two conductors 4, 5. By virtue of the small angle between the two conductors 4, 5, the diode 3 can be easily slid between them and fixed in position. Subsequently, by means of heating, the diode 3 is soldered to both conductors 4, 5. The conductors 4, 5 as well as the diode 3 have been made suitable for this purpose by providing solder dots or balls on a conductor 4, 5 or on the diode 3, and by the presence of a suitable metal on an opposite surface. Next, the diode 3 is provided with an envelope, not shown, for example of an epoxy material. Finally, the redundant parts of the lead frame 11 are removed, for example by cutting. The parts of the connection conductors 4, 5 projecting from the envelope then form the contacts of the device 10 which is ready for mounting on, for example, a PCB (=Printed Circuit Board).

FIGS. 3 and 4 are diagrammatic, plan views of an embodiment of a semiconductor device with a transistor in successive stages of the manufacture carried out by means of a method in accordance with the invention. The manufacture takes place in a way analogous to that described above with respect to an element 3 containing a diode. In this example, (see FIG. 3) the element 3 is a transistor 3. The lower side thereof is a connection region 2, in this case for the collector, and on the upper side there are two connection regions 1A, 1B for the base and the emitter of the, in this case bipolar, transistor 3. The first conductor 4 of the lead frame 11 does not differ from that described in the previous example. In view of the connection regions 1A, 1B on the upper side of the transistor 3, the frame 11A is provided, in this case, with a second and a third, parallel strip-shaped connection conductors 5A, 5B, hereinafter also referred to as the further conductors, of which the end portion is widened, and which run parallel on either side of the conductor 4, and are attached on opposite sides to the frame 11A. In this example, bending (see FIG. 4) takes place along two bending axes B1, B2 which each make an angle of 45 degrees with the longitudinal axis of the conductors 4, 5. By virtue of this and of the geometry of the further conductors 5A, 5B and of the position of the folding lines B1, B2, the widened end portions of the further conductors 5a, 5B become situated, after bending twice through approximately 90 degrees, above the position 4A of the first conductor 4, as indicated in the drawing. Subsequently, from the position shown in FIG. 3 the transistor 3 is slid over the first conductor 4 to the position shown in FIG. 4. The transistor 3 is fixed between, on the one hand, the first conductor 4 and, on the other hand, the further conductors 5A, 5B. After the transistor 3 has been soldered and enveloped, and redundant parts have been removed from the lead frame 11, the device 10 is ready for final mounting.

FIG. 5 is a diagrammatic, perspective view of an embodiment of a semiconductor device with a transistor in a stage of the manufacture carried out using a modification of a method in accordance with the invention. The stage shown in FIG. 5 corresponds to that shown in FIG. 4, yet FIG. 5 depicts the situation prior to the state where the transistor 3 has been slid to a position between the first conductor 4 and the further conductors 5A, 5B.

The difference with the manufacture described with respect to FIG. 4 relates to the position of the transistor 3 before the transistor is slid in between the conductors 4, 5: now the transistor is not situated on the first conductor 4 anterior to the end portion 4A thereof, but on an opposite side thereof within a recess of the lead frame 11. In this example, the lead frame 11 is therefore placed on a substrate 60 which, at the location of the transistor 3 as shown in FIG. 5, comprises an opening 66, not shown in the drawing, below which there is a suction device, not shown either, by means of which the transistor is fixed following its placement in the position shown in FIG. 5.

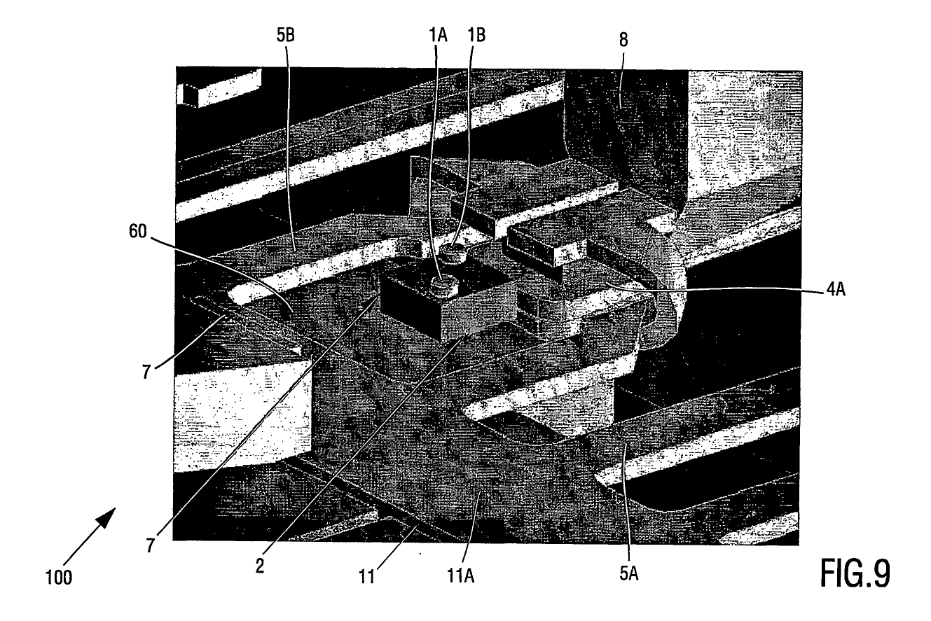

After bending of the further conductors 5A, 5B, which may take place either before or after the shown placement of the transistor 3, said transistor 3 is slid again between the conductors 4, 5. To make this possible, the substrate 60 is provided with a recess at the location of the first conductor 4, and prior to displacing the transistor 3, the first conductor 4 is pressed into the recess over a distance corresponding to the thickness of the lead frame 11 by means of a pressure member 8, as shown in FIG. 9 but not in FIG. 5. After the transistor 3 has been slid between the conductors 4, 5, the pressure member is removed again, thus causing the transistor 3 to be fixed between the conductors 4, 5. The manufacturing process is then continued and completed as described hereinabove.

FIG. 5 further clearly shows that if the end portions 5A, 5B make a small angle with both the longitudinal axis of the conductor 4 and with a direction extending perpendicularly to the longitudinal axis of conductor 4, the element 3 can be slid readily, rapidly and in a self-aligning manner, as it were, between the conductors 4, 5, resulting in said element being tight fit between said conductors. The choice of the direction of the angle with respect to the longitudinal axis of the conductor 4 is determined in this case by the direction from which the element 3 is slid between the conductors 4, 5.

FIG. 6 is a diagrammatically shows a perspective, phantom view of a semiconductor device with a transistor obtained by means of a method as described with respect to FIGS. 3 and 4 or 5. The dimensions of a finished device 10 are, for example, 2×3×1 mm, which are the dimensions of the envelope 9 shown in FIG. 6. The element 3 itself then measures, for example, 0.4×0.4×0.2 mm. The thickness and the width of the conductors 4, 5 are, in this case, 0.1 mm and 0.4 mm respectively. The length of the parts of the conductors 4, 5 projecting from the envelope 9 is approximately 1 mm in this case.

FIGS. 7 through 9 are diagrammatic, perspective views of a device for carrying out a method in accordance with the invention. The device 100 in accordance with the invention comprises (see FIG. 7) a base part 101 supporting a table 102 on which a lead frame 11 can be placed, preferably a frame comprising a large number of lead frames 11. As the table 102 is movable, for example by means of a worm wheel not shown in the drawing, also the lead frame 11 can be displaced. On one side of the frame 11, the device 100 comprises a pusher member 7, in this case in the form of a leaf spring. and a platform 60 which are attached to the base part 101. On the other side there is a pressure member 8 which is movably attached to the table 102.

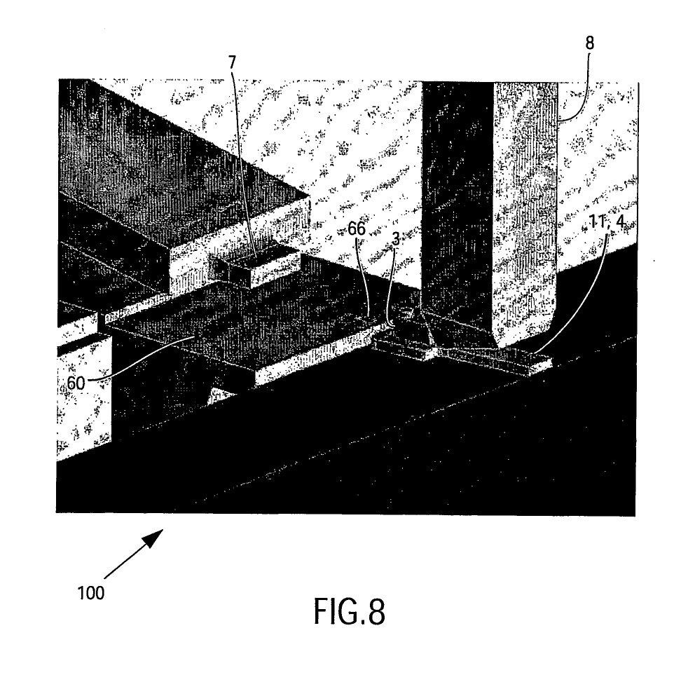

A part of the device 100 is shown in FIG. 8, wherein only a first conductor 4 of the lead frame 11 is depicted. This drawing shows that the platform 60 is provided with an opening 66 on which the element 3 can be positioned by means of a rotatable arm with tweezers, not shown. The opening 66 is connected to a suction device by means of which the element 3 can be fixed following its placement. The Figure further shows that the substrate of the lead frame is provided with a recess in which the conductor track 4 can be pressed downward by means of the pressure member 8. The element 3 can thus readily be slid from the platform 60 onto the first conductor 4 by means of the pressure member 7.

All this is shown again in FIG. 9, wherein the lead frame 11 is shown in its entirety. At this stage, the further conductors 5A, 5B have already been bent towards the first conductor 4 using bending members, not shown. The transistor 3 is now slid to position 4A on the first conductor, the latter being maintained in a pressed-down position by the pressure member 8.

The invention is not limited to the example described, and within the scope of the invention many variations and modifications are possible to those skilled in the art. For example, devices having a different geometry and/or different dimensions can be manufactured. In the examples, the semiconductor frame in question always is in one piece, however, it is alternatively possible to use a semiconductor frame composed of a plurality of parts.

Although an element is attached to the conductors preferably by means of soldering, alternative methods are also possible. For example, a conductive connection may be obtained by using an electroconductive adhesive which is subsequently cured. If the element is interposed between the conductors (which are bent towards each other) by pushing and sliding, such a connection can only be used for the upper side of the element on which no sliding takes place. However, the element may alternatively be brought to its position prior to the bending process. In that case, such a glued joint may be applied to two sides of the element.

1. A lead frame provided with a frame having a first and a second connection conductor, which connection conductors are each connected to the frame and provided with a non-engaging end portion, where, after deformation, the end portion of the second connection conductor can be positioned opposite the first connection conductor, and a semiconductor element can be placed between said connection conductors, characterized in that the end portion of the second connection conductor within the frame is positioned outside the extension of the first connection conductor and can be brought to a position opposite the position of the semiconductor element by bending along a bending axis which is at an oblique angle with respect to the longitudinal axis of the end portion.

2. A lead frame as claimed in claim 1, characterized in that the end portion of the second connection conductor has been brought to a position opposite the position of the semiconductor element by bending along a bending axis which is at an oblique angle with respect to the longitudinal axis of the end portion.

3. A method of manufacturing a semiconductor device comprising the steps of:
providing a semiconductor element having a first and a second electric connection region which connection regions are situated at opposite sides of the semiconductor element;
providing a lead frame as claimed in claim 2; and
fitting the semiconductor element between the end portions of the first connection conductor, where connection means are used to make electroconductive connections between the connection regions and the end portions.

4. A method of manufacturing a semiconductor device comprising the steps of:
providing a semiconductor element having a first and a second electric connection region, which connection regions are situated on opposite sides of the semiconductor element;
providing a lead frame having a frame with a first and a second connection conductor, which connection conductors are each connected to the frame and provided with an exposed end portion;
applying the semiconductor element to the end portion of the first connection conductor, an electroconductive connection between the first connection region and the end portion being made by using a connection means;
moving the end portion of the second connection conductor to a position outside the plane of the frame and opposite a location for the second connection region of the semiconductor element,
making an electroconductive connection between the second connection region and the end portion of the second connection conductor by using a connection means,
characterized in that the end portion of the second connection conductor within the frame is positioned outside the extension of the first connection conductor and is brought to a position opposite the position for the second connection region of the semiconductor element by bending along a bending axis which is at an oblique angle with respect to the longitudinal axis of the end portion.

5. A method as claimed in claim 4, characterized in that the end of the end portion of the second connection conductor is bent through approximately 90 degrees along the bending axis out of the plane of the frame, and the end of the end portion is bent, along a further bending axis extending substantially parallel to the bending axis and at a distance therefrom corresponding approximately to the thickness of the semiconductor element, through an angle of approximately 90 degrees to the position of the semiconductor element.

6. A method as claimed in claim 5, characterized in that the end portion of the second connection conductor is bent along the further bending axis or along another bending axis in such a manner that said end portion extends obliquely in at least one direction with respect to the end portion of the first connection conductor which contains the position for the semiconductor element.

7. A method as claimed in claim 4, characterized in that the semiconductor element is slid between the connection conductors after the end portion of the second connection conductor has been bent to a position opposite the location for the second connection region of the semiconductor element and opposite the end portion of the first connection conductor, the element being clamped between the connection conductors.

8. A method as claimed in claim 3, characterized in that
a lead frame is chosen in which the first connection conductor is provided with a hole at a distance from the position of the semiconductor element;
the semiconductor element is placed on the hole and fixed by means of a suction device present below the hole, after which the semiconductor element is pushed between the connection conductors by means of a pusher member.

9. A method as claimed in claim 3, characterized in that before the semiconductor element is slid between the connection conductors, the end portion of the first connection conductor is maintained in a depressed position by means of a pressure member, until the semiconductor element has been slid between the connection conductors.

10. A device for carrying out a method as claimed in any one of claims 3 through 9, characterized in that the device comprises:
a transport mechanism for a lead frame with at least two connection conductors;
positioning means for positioning a semiconductor element;
pusher means for pushing the semiconductor element (3) in between the two connection conductors, of which one is bent to a position above the position of the other one.

11. A device as claimed in claim 10, which further comprises means for bending an end portion of at least one of the connection conductors along a bending axis which makes an oblique angle with the longitudinal axis of the end portion.

12. A device as claimed in claim 10, characterized in that it comprises pressure means for pressing downward one of the conductor tracks, during the pushing against the semiconductor element.

13. A semiconductor device comprising:
a semiconductor element which is provided with a first and a second electric connection region, which connection regions are situated on opposite sides of the semiconductor element;
a first connection conductor having a contact, and facing away therefrom. an end portion which is electroconductively connected to the first connection region;
a second connection conductor having a contact, and facing away therefrom, an end portion which is bent along a bending axis which is at an oblique angle with respect to the longitudinal axis of the end portion, such that the end portion is situated opposite the second electric connection region, with which it is electroconductively connected, while the contact is situated in the same plane as the contact of the first connection conductor; and
an isolating envelope which leaves contacts facing way from the end portions of the connection conductors uncovered.

14. A semiconductor device as claimed in claim 13, characterized in that:
the semiconductor element is a semiconductor diode;
the second connection conductor is u-shaped or j-shaped prior to bending,
for the oblique angle, an angle in the range between 70 and 80 degrees is selected, and
the contacts of the connection conductors are in line with one another.

15. A semiconductor device as claimed in claim 13, characterized in that:
the semiconductor element is a semiconductor transistor with a third connection region; and
a third connection conductor is present, which has a contact, and facing away therefrom, an end portion which is bent along a bending axis which is at an oblique angle with respect to the longitudinal axis of the end portion, such that the end portion is situated opposite the third electric connection region, with which it is electroconductively connected, while the contact is situated in the same plane as the contact of the first connection conductor;
the second and the third connection conductor are situated on either side of the first connection conductor.

16. A semiconductor device as claimed in claim 13, and a lead frame as claimed in claim 1, characterized in that the first connection conductor is provided with a hole at a distance from the position for the semiconductor element.
